(19) United States
(12) Patent Application Publication
(10) Pub. No.: US 2024/0099157 A1
(43) Pub. Date: Mar. 21, 2024

(54) VARIABLE RESISTANCE ELEMENT AND SEMICONDUCTOR DEVICE INCLUDING THE SAME

(71) Applicant: SK hynix Inc., Icheon-si (KR)

(72) Inventors: Jung Hyeok KWAK, Icheon-si (KR); Tae Yup KIM, Icheon-si (KR); Ku Youl JUNG, Icheon-si (KR); Jin Won JUNG, Icheon-si (KR)

(21) Appl. No.: 18/303,503

(22) Filed: Apr. 19, 2023

(30) Foreign Application Priority Data
Sep. 19, 2022 (KR) 10-2022-0117813

(51) Int. Cl. H10N 50/85; H01F 10/32; H10B 61/00; H10N 50/20

(52) U.S. Cl. CPC H10N 50/85; H01F 10/3222; H01F 10/3254; H10B 61/00; H10N 50/20

(57) ABSTRACT

Variable resistance elements and semiconductor devices including the variable resistance elements are disclosed. In some implementations, a variable resistance element may include a variable resistance element may include a free layer having a variable magnetization direction that switches between different magnetization directions upon application of a magnetic field, a pinned layer having a fixed magnetization direction, and a tunnel barrier layer interposed between the free layer and the pinned layer and including a metal chalcogenide having a cubic crystal structure.

### PRIORITY CLAIM AND CROSS-REFERENCE TO RELATED APPLICATION

This patent document claims the priority and benefits of Korean Patent Application No. 10-2022-0117813 filed on Sep. 19, 2022, which is incorporated herein by reference in its entirety.

### TECHNICAL FIELD

This patent document relates to memory circuits or devices and their applications in semiconductor devices or systems.

### BACKGROUND

The recent trend toward miniaturization, low power consumption, high performance, and multi-functionality in the electrical and electronics industry has compelled the semiconductor manufacturers to focus on high-performance, high capacity semiconductor devices. Examples of such high-performance, high capacity semiconductor devices include memory devices that can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), and an electronic fuse (E-fuse).

### SUMMARY

The disclosed technology in this patent document relates to memory circuits or devices and their applications in semiconductor devices or systems and various implementations of a semiconductor device that can improve the performance of a semiconductor device and reduce manufacturing defects.

In one aspect, a variable resistance element may include: a free layer having a variable magnetization direction; a pinned layer having a pinned magnetization direction; and a tunnel barrier layer interposed between the free layer and the pinned layer and including a metal chalcogenide having a cubic crystal structure.

In another aspect, a semiconductor device may include: a variable resistance layer including a magnetic tunnel junction (MTJ) structure including a free layer having a variable magnetization direction free layer, a pinned layer having a pinned magnetization direction and a tunnel barrier layer interposed between the free layer and the pinned layer and including a metal chalcogenide having a cubic crystal structure; and a selector layer disposed over the variable resistance layer or under the variable resistance layer.

### BRIEF DESCRIPTION OF THE DRAWINGS

FIG. 1A illustrates an example of a variable resistance element based on some implementations of the disclosed technology.

FIG. 1B illustrates another example of a variable resistance element based on some implementations of the disclosed technology.

FIG. 2 is a schematic diagram illustrating an example method for adjusting the lattice constant of the tunnel barrier layer shown in FIG. 1A.

FIG. 3A is a cross-sectional view illustrating an example of a semiconductor device and a method for fabricating the semiconductor device based on some implementations of the disclosed technology.

FIG. 3B is a cross-sectional view illustrating another example of a semiconductor device and a method for fabricating the semiconductor device based on some implementations of the disclosed technology.

FIGS. 4A and 4B illustrate examples of a semiconductor device based on some implementations of the disclosed technology.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

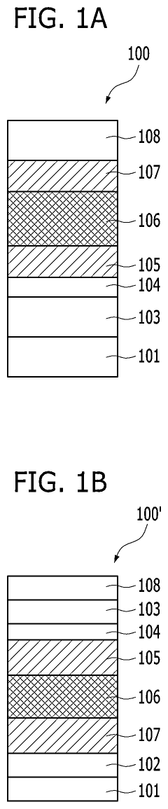

FIG. 1A illustrates an example of a variable resistance element based on some implementations of the disclosed technology.

Referring to FIG. 1, a variable resistance element 100 may include an MTJ structure including a pinned layer 105 having a pinned magnetization direction, a free layer 107 having a variable magnetization direction and a tunnel barrier layer 106 interposed between the free layer 107 and the pinned layer 105.

The pinned layer 105 may have a “pinned” or “fixed” magnetization direction, and thus the magnetization direction of the pinned layer 105 remains unchanged or is prevented from rotating while the magnetization direction of the free layer 107 changes or rotates. In some implementations, the pinned layer 105 may be referred to as a reference layer. In some implementations, the magnetization direction of the pinned layer 105 may be pinned in a first direction (e.g., downward direction). In some implementations, the magnetization direction of the pinned layer 105 may be pinned in a second direction (e.g., upward direction).

The pinned layer 105 may have a single-layer structure or a multilayer structure including a ferromagnetic material. For example, the pinned layer 105 may include an alloy based on at least one of Fe, Ni or Co, for example, an Fe—Pt alloy, an Fe—Pd alloy, a Co—Pd alloy, a Co—Pt alloy, an Fe—Ni—Pt alloy, a Co—Fe—Pt alloy, a Co—Ni—Pt alloy, or a Co—Fe—B alloy, or may include a stack of metals, such as Co/Pt, or Co/Pd or others.

In some implementations, the pinned layer 105 may include a ferromagnetic material having a body-centered cubic (BCC) crystal structure. For example, the pinned layer 105 may include a ferromagnetic material having a BCC (100) crystal structure.

In some implementations, the pinned layer 105 may include a material including Fe and Co.

In addition, the pinned layer 105 may be exchange-coupled with a shift cancelling layer 103 via a spacer layer 104 to form a synthetic anti-ferromagnet (SAF) structure as described below.

The free layer 107 may have different magnetization directions or different electron spin directions and is free to rotate between the different magnetization directions or between the different electron spin directions to switch the polarity of the free layer 107 in the MTJ structure, resulting in changes in resistance value. In some implementations, the polarity of the free layer 107 is changed or rotated (e.g., flipped over) upon application of a voltage or current signal (e.g., a driving current above a certain threshold) to the MTJ structure. With the polarity changes in the free layer 107, the free layer 107 and the pinned layer 105 have different magnetization directions or different electron spin directions, which allows the variable resistance element 100 to store different data or represent different data bits. In some implementations, the free layer 107 may also be referred as a storage layer. The magnetization direction of the free layer 107 may be substantially perpendicular to a surface of the free layer 107, the tunnel barrier layer 106 and the pinned layer 105. In other words, the magnetization direction of the free layer 107 may be substantially parallel to stacking directions of the free layer 107, the tunnel barrier layer 106 and the pinned layer 105. Therefore, the magnetization direction of the free layer 107 may be changed or rotated between a downward direction and an upward direction. The change in the magnetization direction of the free layer 107 may be induced by a spin transfer torque generated by an applied current or voltage.

In some implementations, the free layer 107 may have a single-layer or multilayer structure including a ferromagnetic material. For example, the pinned layer 105 may include an alloy based on at least one of Fe, Ni or Co, for example, an Fe—Pt alloy, an Fe—Pd alloy, a Co—Pd alloy, a Co—Pt alloy, an Fe—Ni—Pt alloy, a Co—Fe—Pt alloy, a Co—Ni—Pt alloy, or a Co—Fe—B alloy, or may include a stack of metals, such as Co/Pt, Co/Pd, or others.

In some implementations, the free layer 107 may include a ferromagnetic material having a body-centered cubic (BCC) crystal structure. For example, the free layer 107 may include a ferromagnetic material a BCC (100) crystal structure.

In some implementations, the free layer 107 may include a material including Fe and Co.

In one implementation, the pinned layer 105 and the free layer 107 may include the same material as each other. In another implementation, the pinned layer 105 and the free layer 107 may include different materials from each other.

In one implementation, the pinned layer 105 and the free layer 107 may have the same thickness as each other. In another implementation, the pinned layer 105 and the free layer 107 may have different thicknesses from each other.

The tunnel barrier layer 106 may allow electrons to tunnel therethrough when reading and writing data. In some implementations, data can be written to the MTJ when a high write current is applied through the tunnel barrier layer 106 to change the magnetization direction of the free layer 107. In this way, the changes in the resistance state of the MTJ represent the data bit written to the variable resistance element. In some implementations, data that is stored in the MTJ can be read from the variable resistance element when a low read current is applied through the tunnel barrier layer 106 without changing the magnetization direction of the free layer 107 to measure the existing resistance state of the MTJ with respect to the existing magnetization direction of the free layer 107.

In some implementations, an insulating oxide material such as MgO, CaO, SrO, TiO, VO or NbO may be used as the tunnel barrier of the MTJ. In order to stably operate a semiconductor device such as a magnetoresistive random-access memory (MRAM), it is necessary to secure the switching reliability of the MTJ. In this regard, it is important to improve the physical property of the tunnel barrier and, in particular, it is necessary to address breakdown issues that may occur in the tunnel barrier including the insulating oxide material. In some implementations, an insulating material undergoes breakdown when the electric field caused by an applied voltage exceeds the dielectric strength of the insulating material. In some implementations, the breakdown of the tunnel barrier may be caused by a bridge phenomenon, in which defects or impurities existing in the tunnel barrier are electrically connected to each other and unintended current flows are caused. In some implementations, the breakdown of the tunnel barrier can be reduced or avoided by increasing the thickness of the tunnel barrier, thereby lowering the probability that defects or impurities are electrically connected to each other. In some implementations, the breakdown of the tunnel barrier can be reduced or avoided by improving characteristics of the tunnel barrier.

The disclosed technology can be implemented in some embodiments to address the breakdown issues of the tunnel barrier including an insulating oxide. In some implementations of the disclosed technology, the tunnel barrier layer 106 may be formed of or include a material which has a greater thickness than the insulating oxide and a low band gap energy (Eg) to reduce the resistance area product (RA).

In some implementations, the tunnel barrier layer 106 may include a metal chalcogenide having a cubic crystal structure.

In some implementations, the tunnel barrier layer 106 may include a metal chalcogenide having a cubic crystal structure and belonging to a space group Fm-3m or F-43m.

In some implementations where each of the pinned layer 105 and the free layer 107 has a body-centered cubic (BCC) crystal structure, the tunnel barrier layer 106 may include a material having a cubic crystal structure and belonging to a space group Fm-3m or F-43m. When the tunnel barrier layer 106 includes a material belonging to a space group other than the space group Fm-3m or F-43m, for example, a space group Pnma or Cmcm, there is a structural mismatch between the tunnel barrier layer 106 and the pinned layer 105/the free layer 107. As a result, spin filtering of the tunnel barrier layer 106 may not work properly.

In some implementations, in order to adjust a lattice constant and a band gap energy, the tunnel barrier layer 106 may include a combination of two or more metal chalcogenides having a cubic crystal structure and/or a cubic crystal structure belonging to a space group Fm-3m or F-43m metal chalcogenide. Here, the combination of two or more metal chalcogenides may be formed by partially or entirely substituting the cation and/or anion of the metal chalcogenide discussed above in place of the cation and/or anion of a metal chalcogenide.

In some implementations, the tunnel barrier layer 106 may include CrS, CrSe, CrTe, MnS, MnSe, MnTe, ZnS, ZnSe, ZnTe, CdS, CdSe, CdTe, GeS, GeSe, GeTe, SnS, SnSe and/or SnTe.

In some implementations, in order to adjust a lattice constant and a band gap energy, the tunnel barrier layer 106 may include a combination of two or more of CrS, CrSe, CrTe, MnS, MnSe, MnTe, ZnS, ZnSe, ZnTe, CdS, CdSe, CdTe, GeS, GeSe, GeTe, SnS, SnSe or SnTe. The combination may include a material in which the cation and/or anion of the material described above is partially or entirely substituted with the cation and/or anion of the other material described above.

In some implementations, the band gap energy of the material included in the tunnel barrier layer 106 may be adjusted to effectively increase a breakdown voltage (Vbd) of the tunnel barrier layer 106.

In some implementations, the lattice constant of the material included in the tunnel barrier layer 106 may be adjusted so that an epitaxy can be formed between the pinned layer 105, the tunnel barrier layer 106 and the free layer 107. In some implementations, in order to secure the conformity of the structure with the pinned layer 105 or the free layer 107, the lattice constant of the tunnel barrier layer 106 may be adjusted to be in the range of 1.7 to 2.3 times the lattice constant of the pinned layer 105 or the free layer 107. When the lattice constant of the tunnel barrier layer 106 is out of the above range, a structure inconsistency with the pinned layer 105 or the free layer 107 may be increased and the spin filtering of the tunnel barrier layer 106 may not operate properly.

In some implementations of the disclosed technology, the tunnel barrier layer 106 may be formed of or include a metal chalcogenide having a cubic crystal structure and low band gap energy (0.5-3 eV) instead of an insulating oxide such as MgOx having a band gap energy (Eg) of 5-7.6 eV. In this way, the tunnel barrier layer 106 can have an increased thickness and a higher breakdown voltage (Vbd) compared to the MgOx (1.1˜1.2 V @ DC bias voltage). As a result, it is possible to effectively improve the breakdown phenomenon of the insulating oxide and improve the switching reliability of the MRAM.

If a voltage or current is applied to the variable resistance element 100, the magnetization direction of the free layer 107 may be changed or rotated by spin transfer torque. In some implementations, when the magnetization directions of the free layer 107 and the pinned layer 105 are parallel to each other, the variable resistance element 100 may be in a low resistance state, and this may indicate a digital data bit “0.” Conversely, when the magnetization directions of the free layer 107 and the pinned layer 105 are anti-parallel to each other, the variable resistance element 100 may be in a high resistance state, and this may indicate a digital data bit “1.” In some implementations, the variable resistance element 100 can be configured to store data bit ‘1’ when the magnetization directions of the free layer 107 and the pinned layer 105 are parallel to each other and to store data bit ‘0’ when the magnetization directions of the free layer 107 and the pinned layer 105 are anti-parallel to each other.

The variable resistance element 100 may further include one or more layers performing various functions to improve a characteristic of the MTJ structure. For example, the variable resistance element 100 may further include at least one of a buffer layer 101, the shift cancelling layer 103, the spacer layer 104 or a capping layer 108.

The buffer layer 101 may be disposed below the shift cancelling layer 103 and may function as a buffer between a substrate and the layers disposed above the buffer layer 101. Further, the buffer layer 101 may facilitate crystal growth of the layers disposed above the buffer layer 101, thus improving properties of the layers disposed above the buffer layer 101. The buffer layer 101 may have a single-layer or a multilayer structure including for example a metal, a metal alloy, a metal nitride, or a metal oxide, or a combination thereof. Moreover, the buffer layer 101 may be formed of or include, for example, a material compatible with a bottom electrode in order to resolve a lattice constant mismatch between the bottom electrode and the layers disposed above the buffer layer 101. For example, the buffer layer 101 may include tantalum (Ta).

The capping layer 108 may be used to protect the variable resistance element 100 and/or function as a hard mask for patterning the variable resistance element 100. In some implementations, the capping layer 108 may include various conductive materials such as a metal. In some implementations, the capping layer 108 may include, for example, a metallic material having almost none or a small number of pin holes, and the capping layer 108 may have a high resistance to wet and/or dry etching. In some implementations, the capping layer 108 may include for example a metal, a nitride, or an oxide, or a combination thereof. For example, the capping layer 108 may include a noble metal such as ruthenium (Ru).

In some implementations, the capping layer 108 may have a single-layer or multilayer structure. In some implementations, the capping layer 108 may have a multilayer structure including an oxide, or a metal, or a combination thereof. For example, the capping layer 108 may have a multilayer structure of an oxide layer, a first metal layer and a second metal layer.

The shift cancelling layer 103 may be used to reduce or offset the effect of a stray magnetic field produced by the pinned layer 105. In this case, the effect of the stray magnetic field of the pinned layer 105 can decrease, and thus a biased magnetic field in the free layer 107 can decrease. The shift cancelling layer 103 may have a magnetization direction anti-parallel to the magnetization direction of the pinned layer 105. In the implementation, when the pinned layer 105 has a downward magnetization direction, the shift cancelling layer 103 may have an upward magnetization direction. Conversely, when the pinned layer 105 has an upward magnetization direction, the shift cancelling layer 103 may have a downward magnetization direction. The shift cancelling layer 103 may be exchange-coupled with the pinned layer 105 via the spacer layer 104 to form a synthetic anti-ferromagnet (SAF) structure. The shift cancelling layer 103 may have a single-layer or multilayer structure including a ferromagnetic material.

A material layer (not shown) for resolving the lattice structure differences and the lattice constant mismatch between the pinned layer 105 and the shift cancelling layer 103 may be interposed between the pinned layer 105 and the shift cancelling layer 103. For example, the material layer may be amorphous and may include a metal, a metal nitride, or metal oxide.

The spacer layer 104 may be interposed between the pinned layer 105 and the shift cancelling layer 103 and function as a buffer between the pinned layer 105 and the shift cancelling layer 103. The spacer layer 104 may be used to implement the anti-ferromagnetic exchange-coupling between the pinned layer 105 and the shift cancelling layer 103 and improve characteristics of the shift cancelling layer 103. The spacer layer 104 may include, for example, a noble metal such as ruthenium (Ru).

In some implementations, the relative positions of the pinned layer 105 and the shift cancelling layer 103 shown in FIG. 1A may be revered.

As such, the disclosed technology can be implemented in some embodiments to provide a MTJ having a high breakdown voltage (Vbd), thereby significantly improving the characteristics of the tunnel barrier layer 106. As a result, it is possible to form a semiconductor device having an improved switching reliability.

In some implementations, the variable resistance element 100 may be formed by sequentially forming a material layer for forming the buffer layer 101, a material layer for forming the shift cancelling layer 103, a material layer for forming the spacer layer 104, a material layer for forming the pinned layer 105, a material layer for forming the tunnel barrier layer 106, a material layer for forming the free layer 107, a material layer for forming the capping layer 108 over the substrate where a predetermined structure is formed, and by sequentially etching, using a hard mask pattern, the material layer for forming the capping layer 108, the material layer for forming the free layer 107, the material layer for forming the tunnel barrier layer 106, the material layer for forming the pinned layer 105, the material layer for forming the spacer layer 104, the material layer for forming the shift cancelling layer 103 and the material layer for forming the buffer layer 101. The material layers except for the material layer for forming the tunnel barrier layer 106 may be formed by a deposition process such as an atomic layer deposition (ALD) process, a chemical vapor deposition (CVD) process, a physical vapor deposition (PVD) process, or a sputtering process. The etching of the material layers for forming the variable resistance element 100 may be performed by a method having strong physical etching characteristics such as an ion beam etch (IBE) process. In some implementations, the variable resistance element 100 may also be formed by another process.

In some implementations, the material layer for forming the tunnel barrier layer 106 may be formed by a sputtering process.

In some implementations, when the tunnel barrier layer 106 includes a combination of two or more metal chalcogenides having a cubic crystal structure, the material layer for forming the tunnel barrier layer 106 may be formed by a sputtering process using a targeted combination having a desired composition.

In some implementations, when the tunnel barrier layer 106 includes a combination of two or more metal chalcogenides having a cubic crystal structure, the material layer for forming the tunnel barrier layer 106 may be formed by a co-sputtering process using a heterogeneous target.

In the implementation shown in FIG. 1A, the free layer 107 is formed over the pinned layer 105. In another implementation, the free layer 107 may be formed under the pinned layer 105. This will be described below with reference to FIG. 1B.

FIG. 1B illustrates another example of a variable resistance element based on some implementations of the disclosed technology. As will be discussed below, some features illustrated in FIG. 1B may differ from those of FIG. 1A.

Referring to FIG. 1B, a variable resistance element 100′ may include a buffer layer 101, an under layer 102, a free layer 107, a tunnel barrier layer 106, a pinned layer 105, a spacer layer 104, a shift cancelling layer 103 and a capping layer 108. The implementation shown in FIG. 1B is different from the implementation shown in FIG. 1A in that the pinned layer 105, the spacer layer 104 and the shift cancelling layer 103 are disposed over the free layer 107 and the variable resistance element 100′ further includes the under layer 102 between the free layer 107 and the buffer layer 101.

The under layer 102 may serve to improve a perpendicular magnetic anisotropy of the free layer 107. The under layer 102 may include may have a single-layer or multilayer structure including a metal, a metal alloy, a metal nitride, or a metal oxide, or a combination thereof.

Since descriptions of the buffer layer 101, the free layer 107, the tunnel barrier layer 106, the pinned layer 105, the spacer layer 104, the shift cancelling layer 103 and the capping layer 108 are substantially the same as those of the implementation shown in FI. 1A, the detailed description is omitted.

In some implementations, the tunnel barrier layer 106 may include a metal chalcogenide having a cubic crystal structure.

In some implementations, the tunnel barrier layer 106 may include a metal chalcogenide having a cubic crystal structure and belonging to a space group Fm-3m or F-43m.

In some implementations where each of the pinned layer 105 and the free layer 107 has a body-centered cubic (BCC) crystal structure, the tunnel barrier layer 106 may include a material having a cubic crystal structure and belonging to a space group Fm-3m or F-43m.

In some implementations, in order to adjust a lattice constant and a band gap energy, the tunnel barrier layer 106 may include a combination of two or more metal chalcogenides having a cubic crystal structure and/or a cubic crystal structure belonging to a space group Fm-3m or F-43m metal chalcogenide.

In some implementations, the tunnel barrier layer 106 may include CrS, CrSe, CrTe, MnS, MnSe, MnTe, ZnS, ZnSe, ZnTe, CdS, CdSe, CdTe, GeS, GeSe, GeTe, SnS, SnSe or SnTe.

In some implementations, in order to adjust a lattice constant and a band gap energy, the tunnel barrier layer 106 may include a combination of two or more of CrS, CrSe, CrTe, MnS, MnSe, MnTe, ZnS, ZnSe, ZnTe, CdS, CdSe, CdTe, GeS, GeSe, GeTe, SnS, SnSe or SnTe.

In some implementations, the band gap energy of the material included in the tunnel barrier layer 106 may be adjusted to effectively increase a breakdown voltage (Vbd) of the tunnel barrier layer 106.

In some implementations, the lattice constant of the material included in the tunnel barrier layer 106 may be adjusted so that an epitaxy can be formed between the pinned layer 105, the tunnel barrier layer 106 and the free layer 107. In some implementations, in order to secure the conformity of the structure with the pinned layer 105 or the free layer 107, the lattice constant of the tunnel barrier layer 106 may be adjusted to be in the range of 1.7 to 2.3 times the lattice constant of the pinned layer 105 or the free layer 107. When the lattice constant of the tunnel barrier layer 106 is out of the above range, a structure inconsistency with the pinned layer 105 or the free layer 107 may be increased and the spin filtering of the tunnel barrier layer 106 may not operate properly.

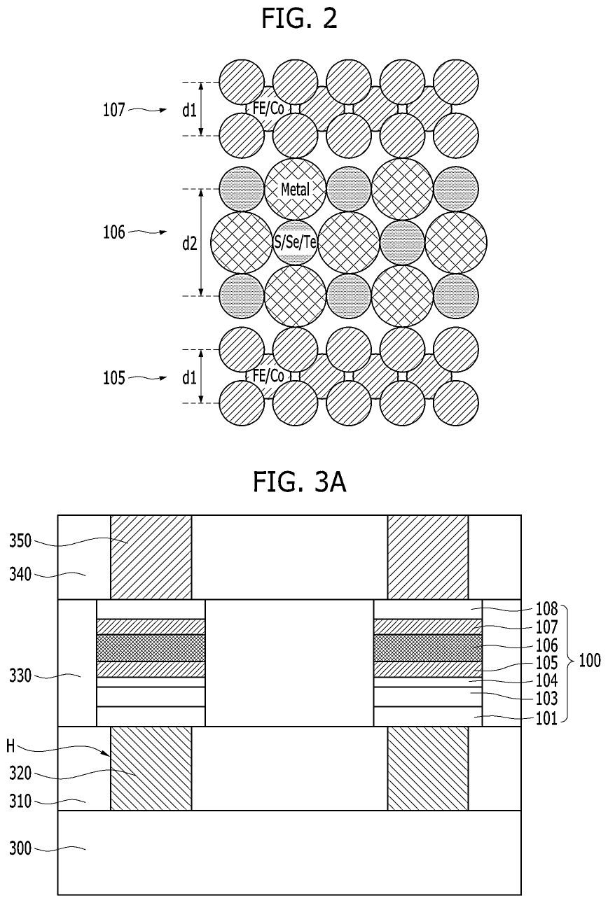

In some implementations, the lattice constant of the tunnel barrier layer shown in FIG. 1A can be adjusted as shown as will be discussed below with reference to FIG. 2.

FIG. 2 is a schematic diagram illustrating an example method for adjusting the lattice constant of the tunnel barrier layer shown in FIG. 1A.

In FIG. 2, each of the free layer 107 and the pinned layer 105 represents an example made of an alloy including Fe and Co, and the tunnel barrier layer 106 represents an example made of a metal chalcogenide having a cubic crystal structure.

As shown in FIG. 2, when the free layer 107 and the pinned layer 105 is formed of or include an Fe—Co alloy having a body-centered cubic (BCC) crystal structure, the tunnel barrier layer 106 may be formed of or include a metal chalcogenide having a cubic crystal structure. At this time, the lattice constant (d2) of the tunnel barrier layer 106 can be adjusted to about twice the lattice constant (d1) of the free layer 107 or the pinned layer 105. As the lattice constant of the tunnel barrier layer 106 is adjusted in this way, an epitaxy can be formed between the free layer 107, the tunnel barrier layer 106 and the pinned layer 105, thereby further improving the performance of the variable resistance element 100.

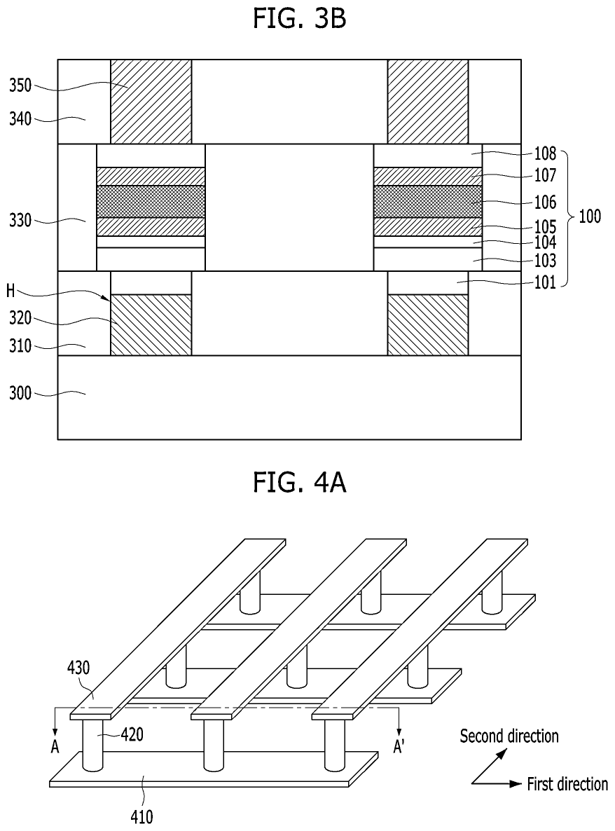

A semiconductor device based on some implementation of the disclosed technology may include a cell array of the variable resistance element 100. The semiconductor device may further include various components such as lines, elements, etc. to drive or control each of the variable resistance elements 100 as will be discussed with reference to FIGS. 3A and 3B.

FIG. 3A is a cross-sectional view illustrating an example of a semiconductor device and a method for fabricating the semiconductor device based on some implementations of the disclosed technology.

Referring to FIG. 3A, a semiconductor device based on some implementations of the disclosed technology may include a substrate 300, lower contacts 320 formed over the substrate 300, corresponding variable resistance elements 100 each formed over a respective one of the lower contacts 320 and upper contacts 350 each formed over a corresponding variable resistance element 100. For each variable resistance element 100, a specific structure for controlling an access to a particular variable resistance element 100, such as a switching circuit/element or transistor, may be provided over the substrate 300 to control the variable resistance element 100, where the switch can be turned on to select the variable resistance element 100 or turned off to unselect the variable resistance element 100. Each lower contact 320 may be disposed over the substrate 300, and couple a lower end of a corresponding variable resistance element 100 to a respective portion of the substrate 300, for example, a drain terminal of the transistor as the switching circuit for the variable resistance element 100. Each upper contact 350 may be disposed over a corresponding variable resistance element 100, and couple an upper end of the variable resistance element 100 to a certain conductive line, for example, a bit line.

A method for manufacturing the semiconductor device based on some implementations of the disclosed technology may include providing the substrate 300 in which the transistor is formed. Then, a first interlayer dielectric layer 310 may be formed over the substrate 300. The lower contacts 320 may be formed by selectively etching the first interlayer dielectric layer 310 to form a plurality of spaced apart holes H. Here, each hole H penetrates through the dielectric layer 310 to expose a corresponding portion of the substrate 300. The holes H may be filled with a conductive material. Then, the variable resistance elements 100 may be formed by forming material layers for the variable resistance elements 100 over the first interlayer dielectric layer 310 and the lower contacts 320. The material layers may be selectively etched to form the plurality of the variable resistance elements 100. Each of the variable resistance elements 100 may be positioned above a corresponding lower contact 320. The etch process for forming the variable resistance element 100 may include an ion beam etching (IBE) method which has a strong physical etching characteristic. Then, a second interlayer dielectric layer 330 may be formed to cover the space between the variable resistance elements 100 over the first dielectric layer 310. Then, a third interlayer dielectric layer 340 may be formed over the variable resistance element 100 and the second interlayer dielectric layer 330, and then upper contacts 650 passing (or extending) through the third interlayer dielectric layer 340 and coupled to an upper end of corresponding variable resistance elements 100 may be formed using similar process steps to what is described above with respect to the lower contacts 320.

In the semiconductor device of FIG. 3A, all layers forming the variable resistance element 100 may have sidewalls aligned with one another. That is because the variable resistance element 100 is formed through an etch process using a single mask.

Unlike the embodiment of FIG. 3A, a part of each of the variable resistance elements 100 may be patterned separately from other parts, as illustrated in FIG. 3B.

FIG. 3B is a cross-sectional view illustrating an example of a semiconductor device and a method for fabricating the semiconductor device based on some implementations of the disclosed technology. As will be discussed below, some features illustrated in FIG. 3B differ from those of FIG. 3A.

Referring to FIG. 3B, the semiconductor device implemented based on some embodiments may include a variable resistance element 100, a part of which, for example, a buffer layer 101 in the variable resistance element 100, has sidewalls that are not aligned with the sidewalls of other layers in the variable resistance element 100. As shown in FIG. 3B, the buffer layer 101 may have sidewalls aligned with the sidewalls of the lower contacts 320.

The semiconductor device in FIG. 3B may be fabricated as will be discussed below.

In some implementations, a first interlayer dielectric layer 310 may be formed over a substrate 300 and then selectively etched to form a plurality of holes H passing through the first interlayer dielectric layer 310 to expose corresponding portions of the substrate 300. Then, the lower contacts 320 may be formed by filling only a lower portion of the holes H. For example, the lower contacts 320 may be formed through a series of processes that form a conductive material to cover the resultant structure having the holes formed therein, and removing a part of the conductive material through an etch back process until the conductive material has a desired thickness. Then, the buffer layer 101 may be formed to fill the remaining portion of each of the holes H. For example, the buffer layer 101 may be formed by forming a material layer for forming the buffer layer 101 which covers the resultant structure in which the lower contacts 320 are formed, and then performing a planarization process such as a CMP (Chemical Mechanical Planarization) until a top surface of the first interlayer dielectric layer 310 is exposed. Then, the remaining portions of the variable resistance element 100 may be formed by forming material layers for forming the remaining layers of the variable resistance element 100 except the buffer layer 101 over the lower contacts 320 and the first interlayer dielectric layer 310.

Subsequent processes are substantially the same as those of FIG. 3A.

In some embodiments, the height which needs to be etched at a time in order to form the variable resistance element 100 can be reduced, lowering the difficulty level of the etch process.

Although FIG. 3B shows the buffer layer 101 of the variable resistance elements 100 is buried in the corresponding holes H, other portions of the variable resistance elements 100 may also be buried in some implementations.

A semiconductor device based on some implementations of the disclosed technology may also include a cell array of the variable resistance element 100′ like the variable resistance element 100 shown in FIGS. 3A and 3B. The semiconductor device may further include various components such as lines, elements, etc. to drive or control each of the variable resistance elements 100′. Since this implementation is substantially the same as those described in FIGS. 3A and 3B, the detailed descriptions are omitted.

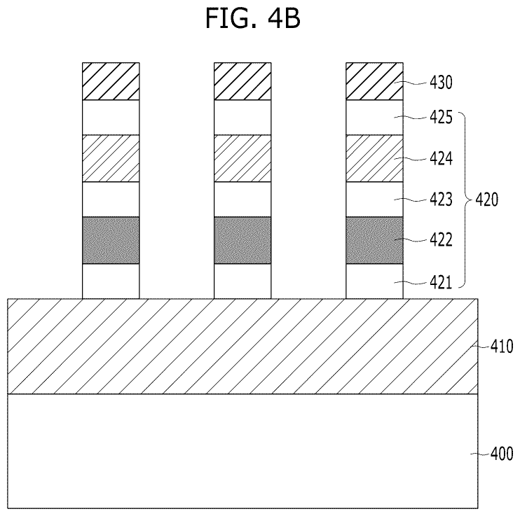

The variable resistance elements 100 and 100′ may be combined with a selection device to form a semiconductor device including memory cells. This will be described in more detail with reference to FIGS. 4A and 4B. FIG. 4A is a perspective view, and FIG. 4B is a cross-sectional view taken along line A-A′ of FIG. 4A.

Referring to FIGS. 4A and 4B, the semiconductor device may include a cross-point structure including a substrate 400, a first conductive line 410 formed over the substrate 400 and extending in a first direction, a second conductive line 430 formed over the first conductive line 410 to be spaced apart from the first conductive line 410 and extending in a second direction crossing the first direction, and memory cells 420 disposed at intersections of the first conductive line 410 and the second conductive line 430 between the first conductive line 410 and the second conductive line 430. In some implementations, the conductive lines can indicate conductive structures that electrically connect two or more circuit elements in the semiconductor memory. In some implementations, the conductive lines include word lines that are used to control access to memory cells in the memory device and bit lines that are used to read out information stored in the memory cells. In some implementations, the conductive lines include interconnects that carry signals between different circuit elements in the semiconductor memory.

The substrate 400 may include a semiconductor material such as silicon. A required lower structure (not shown) may be formed in the substrate 400. For example, the substrate 400 may include a driving circuit (not shown) electrically connected to the first conductive line 410 and/or the second conductive line 430 to control operations of the memory cells 420. In some implementations, the conductive lines can indicate conductive structures that electrically connect two or more circuit elements in the semiconductor device. In some implementations, the conductive lines include word lines that are used to control access to memory cells in the memory device and bit lines that are used to read out information stored in the memory cells. In some implementations, the conductive lines include interconnects that carry signals between different circuit elements in the semiconductor device.

The first conductive line 410 and the second conductive line 430 may be connected to a lower end and an upper end of the memory cell 420, respectively, and may provide a voltage or a current to the memory cell 420 to drive the memory cell 420. When the first conductive line 410 functions as a word line, the second conductive line 430 may function as a bit line. Conversely, when the first conductive line 410 functions as a bit line, the second conductive line 430 may function as a word line. The first conductive line 410 and the second conductive line 430 may include a single-layered structure or a multi-layered structure including one or more of various conductive materials. Examples of the conductive materials may include a metal, a metal nitride, or a conductive carbon material, or a combination thereof, but are not limited thereto. For example, the first conductive line 410 and the second conductive line 430 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAIN), tantalum nitride (TaN), tantalum silicon nitride (TaSiN), tantalum aluminum nitride (TaAIN), carbon (C), silicon carbide (SiC), or silicon carbon nitride (SiCN), or a combination thereof.

The memory cell 420 may be arranged in a matrix having rows and columns arranged in the first direction and the second direction, respectively. The memory cell 420 may be arranged at the intersection regions between the first conductive line 410 and the second conductive line 430. In an implementation, each of the memory cells 420 may have a size that is substantially equal to or smaller than that of the intersection region between each corresponding pair of the first conductive line 410 and the second conductive line 430. In another implementation, each of the memory cells 420 may have a size that is larger than that of the intersection region between each corresponding pair of the first conductive line 410 and the second conductive line 430.

In some implementations, the memory cell 420 has a cylindrical shape. In another implementation, the shape of the memory cell 420 is not limited thereto. For example, the memory cell 420 may have a square pillar shape.

Spaces between the first conductive line 410, the second conductive line 430 and the memory cell 420 may be filled with an insulating material.

The memory cell 420 may include a stacked structure including a lower electrode layer 421, a selector layer 422, a middle electrode layer 423, a variable resistance layer 424 and an upper electrode 425.

The variable resistance layer 424 may include the variable resistance element 100 shown in FIG. 1A and the variable resistance element 100′ shown in FIG. 1B. In some implementations, the detailed description similar to the implementations of FIGS. 1A and 1B will be omitted.

The lower electrode layer 421 may be interposed between the first conductive line 410 and the selector layer 422 and disposed at a lowermost portion of each of the memory cells 420. The lower electrode layer 421 may function as a circuit node that carries a current or applies a voltage between one of the first conductive line 410 and the remaining portion (e.g., the elements 422, 423, 424 and 425) of each of the memory cells 420. The middle electrode layer 423 may be interposed between the selector layer 422 and the variable resistance layer 424. The middle electrode layer 423 may electrically connect the selector layer 422 and the variable resistance layer 424 to each other while physically isolating or separating the selector layer 422 and the variable resistance layer 424 from each other. The upper electrode layer 425 may be disposed at an uppermost portion of the memory cell 420 and function as a transmission path of electrical signals such as a voltage or a current between a material layer in the memory cell 420 and one of the second conductive line 430. At least one of

The lower electrode layer 421, the middle electrode layer 423 and the upper electrode layer 425 may respectively include a single-layered structure or a multi-layered structure including various conductive materials such as a metal, a metal nitride, a conductive carbon material, or a combination thereof. For example, the lower electrode layer 421, the middle electrode layer 423 and the upper electrode layer 425 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAIN), tantalum nitride (TaN), tantalum silicon nitride (TaSiN), tantalum aluminum nitride (TaAIN), carbon (C), silicon carbide (SiC), or silicon carbon nitride (SiCN), or a combination thereof.

The lower electrode layer 421, the middle electrode layer 423 and the upper electrode layer 425 may include the same material as each other or different materials from each other.

The lower electrode layer 421, the middle electrode layer 423 and the upper electrode layer 425 may have the same thickness as each other or different thicknesses from each other.

The selector layer 422 may serve to control access to the variable resistance layer 424 and prevent a current leakage between the memory cells 420 sharing the first line 410 or the second line 430. To this end, the selector layer 422 may have a threshold switching characteristic that blocks or substantially limits a current when a magnitude of an applied voltage is less than a predetermined threshold value and allows the current to increase rapidly when the magnitude of the applied voltage is equal to or greater than the predetermined threshold value. This threshold value may be referred to as a threshold voltage, and the selector layer 422 may controlled to be in either a turned-on or “on” state to be electrically conductive or a turned-off or “off” state to be electrically less-conductive than the “on” state or electrically non-conductive depending on whether the applied voltage is above or below the threshold voltage. Thus, the selector layer 422 exhibits different electrically conductive states to provide a switching operation to switch between the different electrically conductive states by controlling the applied voltage relative to the threshold voltage. The selector layer 422 may include an MIT (Metal Insulator Transition) material such as NbO₂, TiO₂, VO₂, WO₂, or others, an MIEC (Mixed Ion-Electron Conducting) material such as ZrO₂(Y2O₃), Bi₂O₃—BaO, (La₂O₃)ₓ(CeO₂)₁₋ₓ, or others, an OTS (Ovonic Threshold Switching) material including chalcogenide material such as Ge₂Sb₂Te₅, As₂Te₃, As₂, As₂Se₃, or others, or a tunneling insulating material such as silicon oxide, silicon nitride, a metal oxide, or others. A thickness of the tunneling insulating layer is sufficiently small to allow tunneling of electrons under a given voltage or a given current. The selector layer 422 may include a single-layered structure or a multi-layered structure.

In some implementations, the selector layer 422 may perform a threshold switching operation through a doped region formed in a material layer for the selector layer 422. Thus, a size of the threshold switching operation region may be controlled by a distribution area of the dopants. The dopants may form trap sites for charge carriers in the material layer for the selector layer 422. The trap sites may capture the charge carriers moving in the selector layer 422 based on an external voltage applied to the selector layer 422. The trap sites thereby provide a threshold switching characteristic and are used to perform a threshold switching operation.

In some implementations, the selector layer 422 may include a dielectric material having incorporated dopants. The selector layer 422 may include an oxide with dopants, a nitride with dopants, or an oxynitride with dopants, or a combination thereof such as silicon oxide, titanium oxide, aluminum oxide, tungsten oxide, hafnium oxide, tantalum oxide, niobium oxide, silicon nitride, titanium nitride, aluminum nitride, tungsten nitride, hafnium nitride, tantalum nitride, niobium nitride, silicon oxynitride, titanium oxynitride, aluminum oxynitride, tungsten oxynitride, hafnium oxynitride, tantalum oxynitride, or niobium oxynitride, or a combination thereof. The dopants doped into the selector layer 422 may include an n-type dopant or a p-type dopant and be incorporated for example, by ion implantation process. Examples of the dopants may include one or more of boron (B), nitrogen (N), carbon (C), phosphorous (P), arsenic (As), aluminum (Al), silicon (Si) or germanium (Ge). For example, the selector layer 422 may include As-doped silicon oxide or Ge-doped silicon oxide.

The variable resistance layer 424 may be used to store data by switching between different resistance states according to an applied voltage or current.

In some implementations, the variable resistance layer 424 may include the variable resistance element 100 shown in FIG. 1A or the variable resistance element 100′ shown in FIG. 1B. That is, the variable resistance layer 424 may include a stacked structure of the buffer layer 101, the shift cancelling layer 103, the space layer 104, the pinned layer 105, the tunnel barrier layer 106, the free layer 107 and the capping layer 108, or a stacked structure of the buffer layer 101, the under layer 102, the free layer 107, the tunnel barrier layer 106, the pinned layer 105, the spacer layer 104, the shift cancelling layer 103 and the capping layer 108.

In some implementations, the tunnel barrier layer 106 may include a metal chalcogenide having a cubic crystal structure.

In some implementations, the tunnel barrier layer 106 may include a metal chalcogenide having a cubic crystal structure and belonging to a space group Fm-3m or F-43m.

In some implementations where each of the pinned layer 105 and the free layer 107 has a body-centered cubic (BCC) crystal structure, the tunnel barrier layer 106 may include a material having a cubic crystal structure and belonging to a space group Fm-3m or F-43m.

In some implementations, in order to adjust a lattice constant and a band gap energy, the tunnel barrier layer 106 may include a combination of two or more selected from a metal chalcogenide having a cubic crystal structure or metal chalcogenides having a cubic crystal structure belonging to a space group Fm-3m or F-43m metal chalcogenide.

In some implementations, the tunnel barrier layer 106 may include at least one of CrS, CrSe, CrTe, MnS, MnSe, MnTe, ZnS, ZnSe, ZnTe, CdS, CdSe, CdTe, GeS, GeSe, GeTe, SnS, SnSe or SnTe.

In some implementations, in order to adjust a lattice constant and a band gap energy, the tunnel barrier layer 106 may include a combination of two or more of CrS, CrSe, CrTe, MnS, MnSe, MnTe, ZnS, ZnSe, ZnTe, CdS, CdSe, CdTe, GeS, GeSe, GeTe, SnS, SnSe or SnTe.

In some implementations, the band gap energy of the material included in the tunnel barrier layer 106 may be adjusted to effectively increase a breakdown voltage (Vbd) of the tunnel barrier layer 106.

In some implementations, the lattice constant of the material included in the tunnel barrier layer 106 may be adjusted so that an epitaxy can be formed between the pinned layer 105, the tunnel barrier layer 106 and the free layer 107. In some implementations, in order to secure the conformity of the structure with the pinned layer 105 or the free layer 107, the lattice constant of the tunnel barrier layer 106 may be adjusted to be in the range of 1.7 to 2.3 times the lattice constant of the pinned layer 105 or the free layer 107. When the lattice constant of the tunnel barrier layer 106 is out of the above range, a structure inconsistency with the pinned layer 105 or the free layer 107 may be increased and the spin filtering of the tunnel barrier layer 106 may not operate properly.

In some implementations, each of the memory cells 420 includes the lower electrode layer 421, the selector layer 422, the middle electrode layer 423, the variable resistance layer 424 and the upper electrode layer 425, which are sequentially stacked. The structures of the memory cells 420 may vary as long as the memory cells 420 have data storage properties and the disclosed technology is not limited to the structures shown in FIGS. 1A and 1B. In some implementations, at least one of the lower electrode layer 421, the middle electrode layer 423 and the upper electrode layer 425 may be omitted. For example, when the lower electrode layer 421 is omitted, the first conductive line 410 may perform the function of the lower electrode layer 421. When the upper electrode layer 425 is omitted, the second conductive line 430 may perform the function of the upper electrode layer 425. In some implementations, the relative position of the variable resistance layer 424 and the selector layer 422 may be reversed. In some implementations, in addition to the layers 421, 422, 423, 424 and 425 shown in FIG. 4B, the memory cells 420 may further include one or more additional layers (not shown) for enhancing characteristics of the memory cells 420 or improving fabricating processes.

In some implementations, neighboring memory cells of the plurality of memory cells 420 may be spaced apart from each other at a predetermined interval, and trenches may be present between the plurality of memory cells 420. A trench between neighboring memory cells 420 may have a height to width ratio (i.e., an aspect ratio) in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to an upper surface of the substrate 400. In some implementations, neighboring trenches may be spaced apart from each other by an equal or similar distance.

Moreover, the semiconductor device may further include additional layers in addition to the first conductive line 410, the memory cell 420 and the second conductive line 430. For example, the semiconductor device may further include a lower electrode contact disposed between the first conductive line 410 and the lower electrode 421 and/or an upper electrode contact disposed between the second conductive line 430 and the upper electrode 425.

Although one cross-point structure has been described by way of example, two or more cross-point structures may be stacked in a vertical direction perpendicular to a top surface of the substrate 400.

In some implementations, a method for fabricating the semiconductor memory may include the following steps.

The first conductive line 410 may be formed over the substrate 400 in which a predetermined structure is formed. The first conductive line 410 may be formed by forming a conductive layer for forming the first conductive line 410 over the substrate 400 and etching the conductive layer by using a mask pattern in a line shape extending in the first direction.

A material layer for the lower electrode layer 421, a material layer for the selector layer 422, a material layer for the middle electrode layer 423, a material layer for the variable resistance layer 424 and a material layer for the upper electrode layer 425 may be sequentially formed over the first conductive line 410. The memory cell 420 in which the lower electrode layer 421, the selector layer 422, the middle electrode layer 423, variable resistance layer 424 and the upper electrode layer 425 are sequentially stacked may be formed by etching the material layer for the upper electrode layer 425, the material layer for the variable resistance layer 424, the material layer for the middle electrode layer 423, the material layer for the selector layer 422 and the material layer for the lower electrode layer 421 using a mask pattern.

Then, the second conductive line 430 may be formed over the upper electrode layer 425. The second conductive line 430 may be formed by forming a dielectric layer having a trench for forming the second conductive line 430, depositing a conductive layer for forming the second conductive line 430 and etching the conductive layer by using a mask pattern in a line shape extending in the second direction.

Through the method described above, the semiconductor device including the first conductive line 410, the memory cell 420 and the second conductive line 430 may be formed. The memory cell 420 may include the lower electrode layer 421, the selector layer 422, the middle electrode layer 423, the variable resistance layer 424 and the upper electrode layer 425. The variable resistance layer 424 may include a structure in which the buffer layer 101, the shift cancelling layer 103, the spacer layer 104, the pinned layer 105, the tunnel barrier layer 106, the free layer 107 and the capping layer 108 are sequentially stacked, or a structure in which the buffer layer 101, the under layer 102, the free layer 107, the tunnel barrier layer 106, the pinned layer 105, the spacer layer 104, the shift cancelling layer 103 and the capping layer 108 are sequentially stacked.

In some implementations of the disclosed technology, the tunnel barrier layer 106 includes the metal chalcogenide having a cubic crystal structure so that the thickness of the tunnel barrier layer 106 can be increased and the breakdown voltage (Vbd) can be raised. Therefore, it is possible to effectively suppress the breakdown phenomenon in the insulating oxide materials. As a result, the switching reliability of the semiconductor device can be further improved.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub combination. Moreover, although features may be described above as acting in certain combinations and even initially claimed as such, one or more features from a claimed combination can in some cases be excised from the combination, and the claimed combination may be directed to a sub combination or variation of a sub combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Enhancements and variations of the disclosed embodiments and other embodiments can be made based on what is described and illustrated in this patent document.

What is claimed is:

1. A variable resistance element:
a free layer having a variable magnetization direction;
a pinned layer having a fixed magnetization direction; and
a tunnel barrier layer interposed between the free layer and the pinned layer and including a metal chalcogenide having a cubic crystal structure.

2. The variable resistance element according to claim 1, wherein the tunnel barrier layer includes a metal chalcogenide having a cubic crystal structure and belonging to a space group Fm-3m or F-43m.

3. The variable resistance element according to claim 1, wherein the tunnel barrier layer includes a combination of two or more metal chalcogenides.

4. The variable resistance element according to claim 3, wherein the combination has a composition that is configured to adjust a band gap energy (Eg) and a lattice constant of the tunnel barrier layer.

5. The variable resistance element according to claim 1, wherein the tunnel barrier layer includes CrS, CrSe, CrTe, MnS, MnSe, MnTe, ZnS, ZnSe, ZnTe, CdS, CdSe, CdTe, GeS, GeSe, GeTe, SnS, SnSe, or SnTe, or a combination thereof.

6. The variable resistance element according to claim 1, wherein the tunnel barrier layer has a lattice constant that is in a range of 1.7 to 2.3 times a lattice constant of the pinned layer or the free layer.

7. The variable resistance element according to claim 1, wherein the metal chalcogenide exhibits a lower band gap energy (Eg) and a higher breakdown voltage (Vbd) compared to MgOx.

8. The variable resistance element according to claim 1, wherein each of the pinned layer and the free layer includes a material having a body-centered cubic (BCC) crystal structure.

9. The variable resistance element according to claim 1, wherein each of the pinned layer and the free layer includes an alloy containing Fe and Co.

10. A semiconductor device comprising:
a variable resistance layer including a magnetic tunnel junction (MTJ) structure that includes a free layer having a variable magnetization direction that switches between different magnetization directions upon application of a magnetic field, a pinned layer having a fixed magnetization direction and a tunnel barrier layer interposed between the free layer and the pinned layer and including a metal chalcogenide having a cubic crystal structure; and
a selector layer disposed over the variable resistance layer or under the variable resistance layer.

11. The semiconductor device according to claim 10, further comprising a first electrode layer disposed at an uppermost portion of a memory cell including the variable resistance layer and the selector layer, a second electrode layer disposed at a lowermost portion of the memory cell, and a third electrode layer disposed between the variable resistance layer and the selector layer.

12. The semiconductor device according to claim 10, wherein the tunnel barrier layer includes a metal chalcogenide having a cubic crystal structure and belonging to a space group Fm-3m or F-43m.

13. The semiconductor device according to claim 10, wherein the tunnel barrier layer includes a combination of two or more metal chalcogenides.

14. The semiconductor device according to claim 13, wherein the combination has a composition that is configured to adjust a band gap energy (Eg) and a lattice constant of the tunnel barrier layer.

15. The semiconductor device according to claim 13, wherein the tunnel barrier layer includes CrS, CrSe, CrTe, MnS, MnSe, MnTe, ZnS, ZnSe, ZnTe, CdS, CdSe, CdTe, GeS, GeSe, GeTe, SnS, SnSe, or SnTe, or a combination thereof.

16. The semiconductor device according to claim 10, wherein the tunnel barrier layer has a lattice constant that is in a range of 1.7 to 2.3 times a lattice constant of the pinned layer or the free layer.

17. The semiconductor device according to claim 10, wherein the metal chalcogenide exhibits a lower band gap energy (Eg) and a higher breakdown voltage (Vbd) compared to MgOx.

18. The semiconductor device according to claim 10, wherein each of the pinned layer and the free layer includes a material having a body-centered cubic (BCC) crystal structure.

19. The semiconductor device according to claim 10, wherein each of the pinned layer and the free layer includes an alloy containing Fe and Co.
